(19) United States
(12) Patent Application Publication
(10) Pub. No.: US 2003/0008526 A1
(43) Pub. Date: Jan. 9, 2003

(54) Method of forming variable oxide thicknesses across semiconductor chips

(75) Inventors: Jeffrey P. Gambino, Westford, VT (US); Gary B. Bronner, Stormville, NY (US); Carl J. Radens, LaGrangeville, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 09/760,954

(22) Filed: Jan. 16, 2001

(51) Int. Cl. H01L 21/31; H01L 21/469

(52) U.S. Cl. 438/787; 438/785; 438/786; 438/778

(57) ABSTRACT

A method for protecting selected first surfaces on a semiconductor substrate during application of a second oxide layer to said substrate comprising applying an oxidation barrier layer as a mask over said selected first surfaces, prior to patterning said semiconductor substrate with a resist mask and applying said second oxide layer.

### BACKGROUND OF THE INVENTION

The present invention relates to processes for the fabrication of integrated circuit devices on semiconductor substrates. In particular, the present invention relates to processes by which oxide dielectric layers featuring variable thicknesses are fabricated across a semiconductor substrate surface.

In producing DRAM integrated circuits, varying oxide thicknesses are required to be fabricated across the regions (i.e., array/regions vs. supports regions) of the semiconductor chip in order to be compatible with the different voltage requirements. Previously practiced processes for fabricating these different gate oxides on the same wafer typically employ methods that involve the removing the thick oxide from regions where a thin oxide is required. In the prior art, the thick oxide is masked by photoresist to protect it from the etch process. However, these procedures typically expose the thick gate oxide area to photoresist which results in contaminating the gate oxide surface with the inherent impurities commonly included in photoresist compositions.

### SUMMARY OF THE INVENTION

Now, according to the present invention, an improved method has been developed to protect selected chip features during oxidation processes. An oxidation barrier is used to mask chip features which require protection during oxidation processes employed to form enhanced oxide thicknesses in areas of a semiconductor substrate where a thicker oxide layer is desirable.

The presently invented process is designed for producing a first, thin layer of oxide upon a first surface region of a semiconductor substrate and for forming a second, thick oxide layer, of greater thickness than the first layer of oxide upon a second surface region of the semiconductor substrate.

In one embodiment, a first oxide (for example, SiO₂, Al₂O₃, HfO₂, TiO₂; a preferred oxide is silicon oxide) layer is formed upon a first and second semiconductor substrate region. Preferably, this SiO₂ layer is about 0.5 to about 10 nm thick; most preferably, the SiO₂ layer is about 1 to about 2 nm. The SiO₂ typically is grown by thermal oxidation, or deposited by low pressure chemical vapor deposition (LPCVD) or by plasma-enhanced chemical vapor deposition (PECVD). Then, an oxidation barrier (for example, a nitride such as SiN, TiN, HfN, ZrN; a preferred nitride is silicon nitride) or, alternatively, a metal (such as Ti, HfH, or Zr) layer is formed over the initial oxide layer. Preferably, a SiN layer is formed to a thickness of about 5 to about 100 nm, most preferably about 10 to about 20 nm. Typically, the SiN is deposited by low pressure chemical vapor deposition (LPCVD) or by plasma-enhanced chemical vapor deposition (PECVD). Using lithographic processes, the silicon oxide and silicon nitride layers are patterned to expose the layers over the second substrate region on which a second thicker oxide layer will be formed. The exposed silicon nitride and first oxide layers over the second semiconductor substrate region are selectively removed. Typically, the SiN layer is etched using a F-based dry etch technique; the SiO₂ layer typically is etched using a HF-based wet etch technique. The resist mask then is stripped, and the semiconductor substrate wafer is cleaned to remove resist contaminants. The wafer then is subjected to a thermal oxidation procedure, which results in a second thicker (preferably about 3 to about 50 nm) oxide being grown in the second semiconductor substrate region where bare Si is exposed, and a thinner (at least about 1 to about 5 nm thinner than the thicker SiO₂ layer) layer of silicon oxynitride (SiON) in the first substrate region where the SiN layer mask is present.

In a second embodiment, a thin nitride (such as SiN, TiN, HfN, or ZrN; SiN is preferred) layer (preferably, about 1 to about 3 nm) first is applied over first and second semiconductor substrate regions. Typically, a SiN is deposited by low pressure chemical vapor deposition (LPCVD) or by plasma-enhanced chemical vapor deposition (PECVD). This is followed by the deposition of a layer (preferably, about 5 to about 20 nm) of a sacrificial oxide film, typically by LPCVD or PECVD techniques. Using lithographic techniques, the sacrificial oxide is patterned to expose the layers over the second region of substrate on which a second thicker oxide layer will be formed. The exposed sacrificial oxide and silicon nitride are selectively removed. Typically, the SiN layer is etched using a H₃PO₄-based wet etch technique; the SiO₂ layer typically is etched using a F-based dry etch technique. The resist mask then is stripped and the sacrificial oxide is removed (typically using a HF-based wet etch). The wafer then is subjected to a thermal oxidation procedure, which results in a second thicker (preferably about 3 to about 50 nm) oxide being grown in the second semiconductor substrate region where bare Si is exposed, and a thinner (about 1 to about 5 nm thinner than the thicker SiO₂ layer) layer of oxynitride (e.g., SiON, TiON, ZRON, or HfON) in the first substrate region where the nitride layer mask is present.

In yet another embodiment, a thin nitride (e.g., SiN, TiN, ZrN, or HfN) layer (preferably, about 1 to about 3 nm) first is applied over a first and second semiconductor substrate regions. Typically, the nitride is deposited by low pressure chemical vapor deposition (LPCVD) or by plasma-enhanced chemical vapor deposition (PECVD). Using lithographic techniques, the SiN layer is patterned to expose the second region of substrate on which a second thicker oxide layer will be formed. The exposed SiN is selectively removed, typically by using a CF₄/O₂ down-stream plasma etch, and then the resist mask is stripped. The wafer then is subjected to a thermal oxidation procedure, which results in a second thicker (preferably about 3 to about 50 nm) oxide being grown in the second semiconductor substrate region where bare Si is exposed, and a thinner (about 1 to about 5 nm thinner than the thicker SiO₂ layer) layer of oxynitride (e.g., SiON) dielectric in the first substrate region where the SiN layer mask is present.

### BRIEF DESCRIPTION OF THE DRAWINGS

FIGS. 1-4 are sectional views illustrating the process steps in accordance with one embodiment of the present invention.

FIGS. 5-9 are sectional views depicting the process steps in accordance with a second embodiment of the present invention.

FIGS. 10-16 are sectional views representing the process steps used in accordance with a third embodiment of the present invention.

### DETAILED DESCRIPTION OF PREFERRED EMBODIMENTS

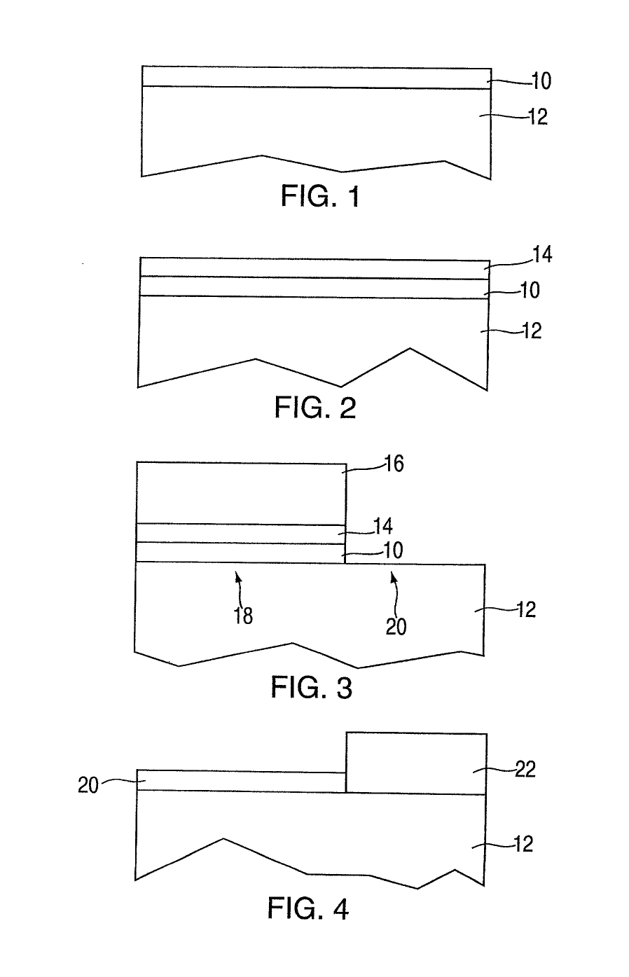

Referring now to FIGS. 1 through 4, these figures are sectional views illustrating a sequence of process steps utilized for the formation of varying oxide thicknesses across the features of a semiconductor chip.

In FIG. 1, a first oxide layer 10 is deposited or grown upon a silicon semiconductor substrate 12 using conventional methods. The oxide layer 10 is formed with a thickness of about 1 nm.

As shown in FIG. 2, a layer of silicon nitride 14 then is deposited over oxide layer 10, to a thickness of about 1 nm. Employing conventional lithographic processes, silicon nitride layer 14 is patterned with resist pattern 16 which serves to protect a selected first region of the semiconductor chip while leaving a second region exposed. The exposed silicon nitride 14 and oxide 10 above the second substrate region 20 are selectively removed, as depicted in FIG. 3, using standard etching techniques. The resist masking layer 16 then is stripped from the silicon nitride layer 14 over the first substrate region 18, and a second thicker oxide layer 22 is grown over the second substrate region 20, resulting in the structure shown in FIG. 4, featuring a semiconductor substrate 12 with oxide layers 20 and 22 of two different thicknesses.

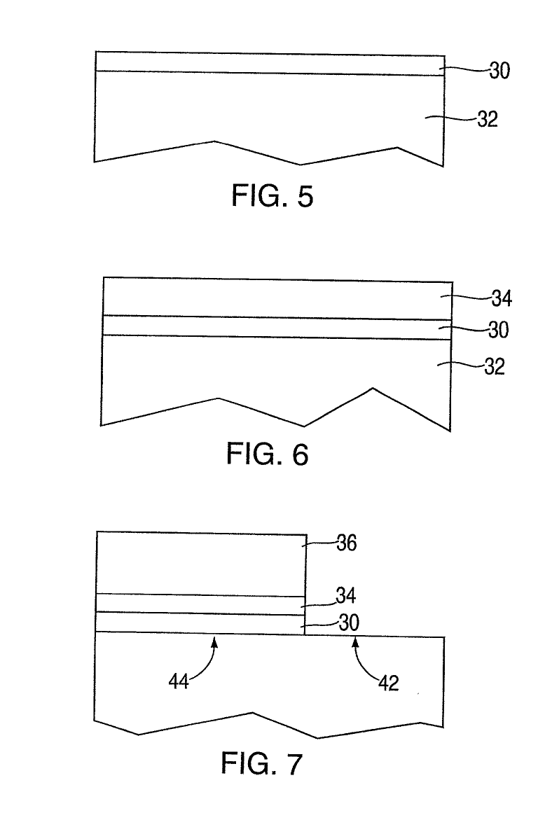

Referring to FIGS. 5 through 9, sectional views are shown representing a sequence of process steps utilized in a second embodiment of the present invention for the formation of varying oxide thicknesses across the features of a semiconductor chip. As depicted in FIG. 5, a layer of silicon nitride 30 first is applied over the surface of semiconductor substrate 32. Then, as seen in FIG. 6, a sacrificial oxide layer 34 is deposited over the silicon nitride layer 30 to a thickness of about 5 to about 20 nm.

Employing conventional lithographic processes, the sacrificial oxide 34 is patterned with a resist layer 36, as shown in FIG. 7, and then unprotected areas of the sacrificial oxide layer 34 and the silicon nitride layer 30 are selectively removed, using standard etching techniques to expose second substrate region 42 while not disturbing first substrate region 44.

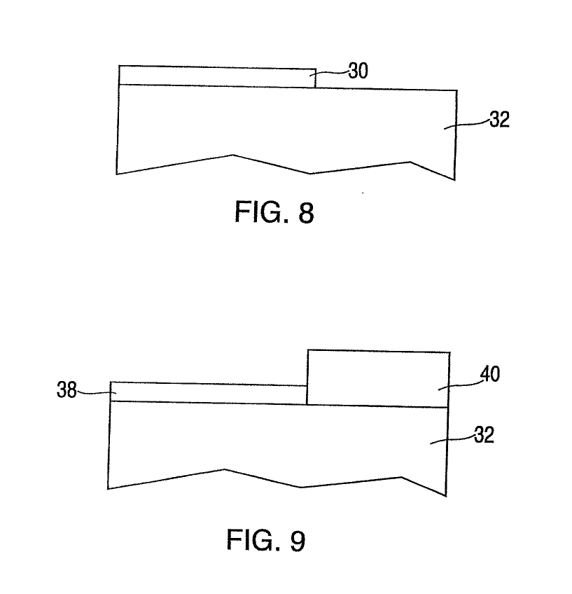

The resist mask 36 then is stripped from the sacrificial oxide layer above first substrate region 44, and sacrificial oxide layer 34 is removed as well, resulting in the arrangement as illustrated in FIG. 8. Thermal oxidation then is performed to produce a second, thicker oxide 40 in the area above second substrate region 42 and convert the SiN layer to SiON in the area above the first substrate region 44, as depicted in FIG. 9, featuring a semiconductor substrate 32 with oxide layers 38 and 40 of two different thicknesses.

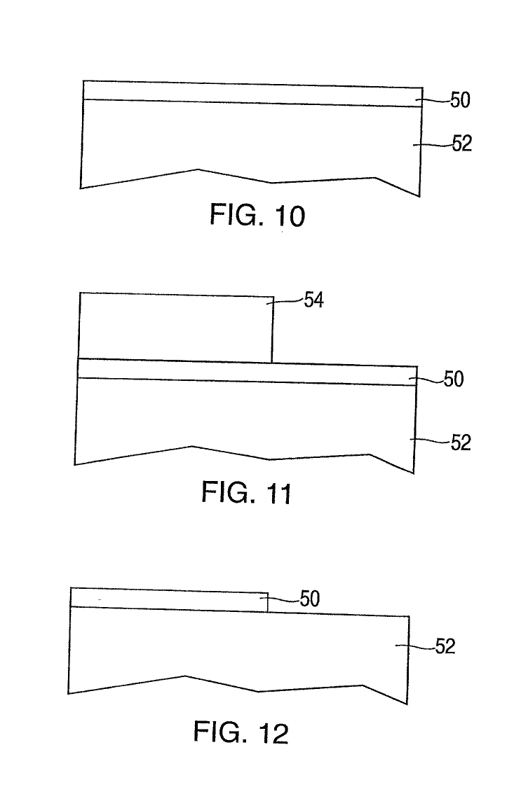

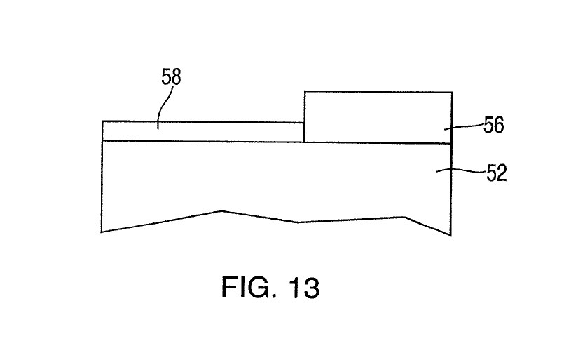

In a third embodiment, illustrated by FIGS. 10-13, a thin SiN layer 50 is deposited over the surface of a semiconductor substrate 52, to result in the structure of FIG. 10. Using standard lithographic techniques, the SiN layer 50 is patterned with resist 54 to protect a first substrate region and expose the SiN layer over a second substrate region. The exposed SiN is etched by a plasma etching technique, and then resist 54 is stripped to form the structure of FIG. 11. A thermal oxidation then is conducted to produce a second, thicker oxide 56 in the area above second substrate region and a thin SiON layer 58 over the first substrate region to produce a structure, as in FIG. 13.

While preferred embodiments have been shown and described, various modifications and substitutions maybe made thereto without departing from the spirit and scope of the invention. Accordingly, it is to be understood that the present invention has been described by way of illustration only, and such illustrations and embodiments as have been disclosed herein are not to be construed as limiting to the scope of the claims.

We claim:

1. A method of forming oxide layers of varying thicknesses over first and second regions of a semiconductor substrate surface comprising:
applying an oxidation barrier layer over the first region of the substrate surface;
depositing an oxide layer of one thickness over the second region of the substrate surface; and
converting the barrier layer to form an oxide layer of another thickness over the first region of the substrate surface.

2. The method of claim 1 wherein said oxidation barrier layer is a layer selected from the group consisting of a nitride layer and a metal layer.

3. The method of claim 2 wherein said nitride layer is selected from the group consisting of SiN, TiN, HfN, and ZrN.

4. The method of claim 3 wherein said nitride layer is SiN.

5. The method of claim 2 wherein said metal layer is selected from the group consisting of Ti, Hf, and Zr.

6. A method for fabricating integrated circuit devices on a semiconductor substrate comprising:
forming a first oxide layer over first and second semiconductor substrate regions;
forming an oxidation barrier layer over the first oxide layer;
patterning the oxidation barrier layer with a resist mask to expose the area above the second semiconductor substrate region;
removing the oxidation barrier layer and the first oxide layer over the second semiconductor substrate area; and
growing a second oxide layer over the second semiconductor substrate region, wherein said second oxide layer has a thickness greater then said first oxide layer.

7. The method of claim 6 wherein said oxidation barrier layer is a layer selected from the group consisting of a nitride layer and a metal layer.

8. The method of claim 7 wherein said nitride layer is selected from the group consisting of SiN, TiN, HfN, and ZrN.

9. The method of claim 7 wherein said metal layer is selected from the group consisting of Ti, HfN, and Zr.

10. The method of claim 8 wherein said nitride layer is SiN.

11. The method of claim 6 wherein said first oxide layer has a thickness ranging from about 0.5 to about 10 nm and said second oxide layer has a thickness ranging from about 3 to about 50 nm, and wherein said first oxide layer is at least about 1 to about 5 nm thinner than said second oxide layer.

12. A method for fabricating integrated circuit devices on a semiconductor substrate comprising:
forming a nitride layer over a first and a second semiconductor substrate region;
depositing a layer of sacrificial oxide over the nitride layer;
patterning the sacrificial oxide with a resist mask to expose the area above the second semiconductor substrate region;
removing the sacrificial oxide and the nitride layer in the area above the second semiconductor substrate region;
removing the resist mask and the sacrificial oxide layer from the area above the first semiconductor substrate region; and
growing a second oxide layer over the second semiconductor substrate region, wherein said second oxide layer has a thickness greater than a first oxide layer over the first semiconductor substrate region.

13. The method of claim 12 wherein said nitride layer is selected from the group consisting of SiN, TiN, HfN, and ZrN.

14. The method of claim 13 wherein said nitride layer is SiN.

15. The method of claim 12 wherein said first oxide layer has a thickness ranging from about 0.5 to about 10 nm and said second oxide layer has a thickness ranging from about 3 to about 50 nm, and wherein said first oxide layer is at least about 1 to about 5 nm thinner than said second oxide layer.

16. A method for fabricating integrated circuit devices on a semiconductor substrate comprising:
forming a nitride layer over a first and second semiconductor substrate region;
forming an oxide layer over the nitride layer;
patterning the oxide layer with a resist mask to expose the area above the second semiconductor substrate region;
removing the oxide layer in the area above the second semiconductor substrate region;
removing the resist mask from the area above the first semiconductor substrate region;
removing the oxide layer in the area above the first semiconductor substrate region; and
growing a second oxide layer over the second semiconductor substrate region, wherein said second oxide layer has a thickness greater than a first oxide layer over the first semiconductor substrate region.

17. The method of claim 16 wherein said nitride layer is selected from the group consisting of SiN, TiN, HfN, and ZrN.

18. The method of claim 17 wherein said nitride layer is SiN.

19. The method of claim 16 wherein said first oxide layer has a thickness ranging from about 0.5 to about 10 nm and said second oxide layer has a thickness ranging from about 3 to about 50 nm, and wherein said first oxide layer is at least about 1 to about 5 nm thinner than said second oxide layer.

20. A method for fabricating integrated circuit devices on a semiconductor substrate comprising:
forming a nitride layer over a first and a second semiconductor substrate region;
patterning the nitride layer with a resist mask to expose the area above the second semiconductor substrate region;
removing the nitride layer in the area above the second semiconductor substrate region;
removing the resist mask from the area above the first semiconductor substrate region; and
growing a second oxide layer over the second semiconductor substrate region, wherein said second oxide layer has a thickness greater than a first oxide layer over the first semiconductor substrate region.

21. The method of claim 20 wherein said nitride layer is selected from the group consisting of SiN, TiN, HfN, and ZrN.

22. The method of claim 21 wherein said nitride layer is SiN.

23. The method of claim 20 wherein said first oxide layer has a thickness ranging from about 0.5 to about 10 nm and said second oxide layer has a thickness ranging from about 3 to about 50 nm, and wherein said first oxide layer is at least about 1 to about 5 nm thinner than said second oxide layer.
